(19) United States
(12) Patent Application Publication
(10) Pub. No.: US 2017/0074157 A1
(43) Pub. Date: Mar. 16, 2017

(54) SYSTEMS AND METHOD FOR HARVESTING ENERGY FROM A TURBOCHARGER WASTEGATE

(71) Applicant: General Electric Company, Schenectady, NY (US)

(72) Inventors: Shivraj Subhash Mitkari, Bangalore (IN); Sujith Mohan, Bangalore (IN); Pavan Chakravarthy Nandigama, Bangalore (IN); Amit Shrivastava, Bangalore (IN); Rajesh Katta, Bangalore (IN); Kothamasu Venkata Krishna Chaitanya, Bangalore (IN)

(21) Appl. No.: 14/855,934

(22) Filed: Sep. 16, 2015

(51) Int. Cl. F02B 37/00; H01L 35/30; H02N 10/00

(52) U.S. Cl. CPC F02B 37/005; H02N 10/00; H01L 35/30

(57) ABSTRACT

A system includes a turbocharger, a wastegate, and one or more thermoelectric generators. The turbocharger includes a turbine and a compressor, and is configured to be coupled to an internal combustion engine. The wastegate is coupled to the turbine, and is disposed within a wastegate enclosure. The one or more thermoelectric generators generate energy from engine exhaust flowing through the wastegate. Each of the thermoelectric generators comprising includes a hot side coupled to the wastegate enclosure, a cold side coupled to a coolant supply, and one or more thermoelectric materials disposed between the hot side and the cold side.

### BACKGROUND

The subject matter disclosed herein relates to internal combustion engine driven system, and more specifically powering components within an internal combustion engine driven system.

Combustion engines combust fuel to generate motion of certain interior components within the engine, which is then typically used to power a drive train, a generator, some other load, or other useful system. Combustion engines typically combust a carbonaceous fuel, such as natural gas, gasoline, diesel, and the like, and use the corresponding expansion of high temperature and high pressure gases to apply a force to certain components of the engine (e.g., a piston disposed in a cylinder) to move the components over a distance. Each cylinder may include one or more valves that open and close correlative with combustion of the carbonaceous fuel. For example, an intake valve may direct an oxidant such as air into the cylinder, which is then mixed with fuel and combusted. Combustion fluids (e.g., hot gases) may then be directed to exit the cylinder via an exhaust valve. The engine may include one or more turbochargers (e.g., a single stage turbocharger, a twin stage turbocharger, etc.) to increase the pressure and/or quantity of air that combines with the fuel within the cylinder. The turbocharger may work by rotating two sides of a rotor. The first receives pressure from exhaust gas which rotates blades of the turbocharger. The other side of the turbocharger also has blades that spin and force additional oxidant into the cylinder of the engine. Accordingly, the carbonaceous fuel is transformed into mechanical motion, useful in driving a load. For example, the load may be a generator that produces electric power.

Typically, auxiliary components, such as air conditioning systems, oil pumps, starter motors, and the like may be powered by a belt, or some other way that is driven by the engine, thus increasing the load on the engine. Increasing fossil fuel costs, the limited supply of fossil fuels, and the effect of carbonaceous emissions on the environment, among other factors, have increased the desirability for improving the efficiency of internal combustion engines.

### BRIEF DESCRIPTION

Certain embodiments commensurate in scope with the originally claimed subject matter are summarized below. These embodiments are not intended to limit the scope of the claimed subject matter, but rather these embodiments are intended only to provide a brief summary of possible forms of the subject matter. Indeed, the subject matter may encompass a variety of forms that may be similar to or different from the embodiments set forth below.

In a first embodiment, a system includes a turbocharger, a wastegate, and one or more thermoelectric generators. The turbocharger includes a turbine and a compressor, and is configured to be coupled to an internal combustion engine. The wastegate is coupled to the turbine, and is disposed within a wastegate enclosure. The one or more thermoelectric generators generate energy from engine exhaust flowing through the wastegate. Each of the thermoelectric generators includes a hot side coupled to the wastegate enclosure, a cold side coupled to a coolant supply, and one or more thermoelectric materials disposed between the hot side and the cold side.

In a second embodiment, an engine driven system includes an internal combustion engine, an intake manifold, and exhaust manifold, a turbocharger, a wastegate, an intercooler, a coolant supply, and a thermoelectric generator. The intake manifold is disposed upstream of the internal combustion engine. The exhaust manifold is disposed downstream of the internal combustion engine. The turbocharger is coupled to the internal combustion engine, and includes a turbine and a compressor. The wastegate is coupled to the turbine and disposed within a wastegate enclosure. The wastegate regulates an amount of engine exhaust to the turbine by diverting engine exhaust away from the turbine. The intercooler is coupled to the turbocharger and the intake manifold. The coolant supply supplies coolant to a coolant inlet of the intercooler. The thermoelectric generator generates energy from engine exhaust flowing through the wastegate. The thermoelectric generator includes a hot side coupled to the wastegate enclosure, a cold side coupled to the coolant inlet of the intercooler, and one or more thermoelectric materials disposed between the hot side and the cold side.

In a third embodiment, a method includes operating an engine driven system, harvesting energy via one or more thermoelectric generators, and powering one or more components using energy harvested by the one or more thermoelectric generators. The engine driven system includes an internal combustion engine, a turbocharger coupled to the internal combustion engine, a wastegate coupled to the turbocharger and disposed within a wastegate enclosure, and an intercooler having a coolant inlet. The one or more thermoelectric generators includes a hot side coupled to the wastegate enclosure, a cold side coupled to the coolant inlet of the intercooler, and one or more thermoelectric materials disposed between the hot side and the cold side.

### BRIEF DESCRIPTION OF THE DRAWINGS

These and other features, aspects, and advantages of the present disclosure will become better understood when the following detailed description is read with reference to the accompanying drawings in which like characters represent like parts throughout the drawings, wherein:

FIG. 1 is a block diagram of an embodiment of an engine driven system in accordance with aspects of the present disclosure;

FIG. 2 is a schematic of an embodiment of the engine driven system having multiple thermoelectric generators coupled to the wastegate in accordance with aspects of the present disclosure;

FIG. 3 is a schematic of one embodiment of a thermoelectric generator in accordance with aspects of the present disclosure;

FIG. 4 is a section view of multiple thermoelectric generators disposed about a wastegate enclosure or a discharge duct with in accordance with aspects of the present disclosure; and

FIG. 5 is a process of using one or more thermoelectric generators to power components or charge a battery in accordance with aspects of the present disclosure.

### DETAILED DESCRIPTION

One or more specific embodiments of the present disclosure will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” “the,” and “said” are intended to mean that there are one or more of the elements. The terms “comprising,” “including,” and “having” are intended to be inclusive and mean that there may be additional elements other than the listed elements.

Typically, in an internal combustion system, a number of components such as air conditioning systems, oil pumps, starter motors, and the like are powered directly by the engine (e.g., via a belt or some other way), thus increasing the load on the engine. In such an embodiment, energy used to drive components is subtracted from the energy produced by the engine that goes toward mechanical motion, powering a generator, etc. Moreover, there are places within the engine driven system where energy (e.g., in the form of heat) is being wasted. Accordingly, the present disclosure relates to harvesting energy where it is typically wasted (e.g., the wastegate of a turbocharger) to power components that are typically driven by the engine.

During use, a turbocharger forces extra air (and proportionally more fuel) into a combustion chamber of a combustion engine increasing the power and/or the efficiency (e.g., fuel efficiency) of the combustion engine. This is achieved by using the engine exhaust to drive a turbine wheel in a turbine of the turbocharger. The turbine wheel drives a shaft coupled to a compressor wheel in a compressor of the turbocharger which pressurizes intake air, previously at atmospheric pressure, and forces it typically through an intercooler and over a throttle valve and into an engine intake manifold. Boost pressure is limited to keep the entire engine system, including the turbocharger, inside operating range (e.g., thermal and mechanical design operating ranges). A wastegate (e.g., wastegate valve) may be disposed between exhaust manifold discharge and the exhaust system to regulate the amount of exhaust directed to the turbocharger. The wastegate 16 functionally regulates the amount of engine exhaust provided to the turbine 36 of the turbocharger 14 by diverting engine exhaust in the engine exhaust duct 42 to the exhaust discharge duct 50. The high energy of the engine exhaust flowing through the discharge duct is typically wasted energy. By using a thermoelectric generator to harvest that energy and power components that are typically directly driven by the engine, the efficiency of the engine driven system may be improved.

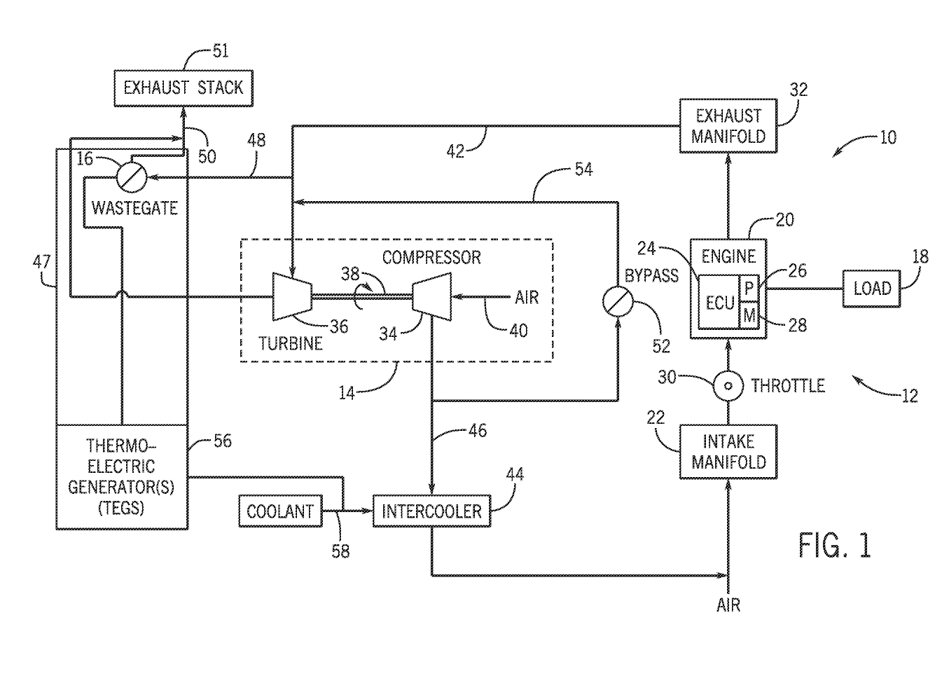

Turning to the figures, FIG. 1 illustrates a block diagram of an embodiment of an engine driven system 10 (e.g., engine driven power generation system) having an internal combustion system 12 coupled to a turbocharger 14 that is coupled to a wastegate 16. The system 10 may include a vehicle, such as a locomotive, an automobile, a bus, or a boat. Alternatively, the system 10 may include a stationary system, such as a power generation system having the internal combustion system 12 coupled to a load 18. Beyond power generation, the system 10 may be utilized in other applications such as those that recover heat and utilize the heat (e.g., combined heat and power applications), combined heat, power, and cooling applications, applications that also recover exhaust components (e.g., carbon dioxide) for further utilization, gas compression applications, and mechanical drive applications.

The internal combustion system 12 includes an engine 20 (e.g., a reciprocating internal combustion engine) having one or more combustion chambers (e.g., 1, 2, 3, 4, 5, 6, 7, 8, 10, 12, 14, 16, 18, 20, or more combustion chambers). An air supply is configured to provide a pressurized oxidant, such as air, oxygen, oxygen-enriched air, oxygen-reduced air, or any combination thereof, to each combustion chamber. The combustion chamber is also configured to receive a fuel (e.g., a liquid and/or gaseous fuel) from a fuel supply, and a fuel-air mixture ignites and combusts within each combustion chamber. The hot pressurized combustion gases cause a piston adjacent to each combustion chamber to move linearly within a cylinder and convert pressure exerted by the gases into a rotating motion, which causes a shaft to rotate. Further, the shaft may be coupled to a load, which is powered via rotation of the shaft. For example, the load may be any suitable device that may generate power via the rotational output of the system 10, such as the load 18. Additionally, although the following discussion refers to air as the oxidant, any suitable oxidant may be used with the disclosed embodiments. Similarly, the fuel may be any suitable gaseous fuel, such as natural gas, associated petroleum gas, propane, biogas, sewage gas, landfill gas, and coal mine gas, for example. Also, the fuel may be any suitable liquid fuel, such as gasoline, diesel, and alcohol fuels, for example.

The engine 20 may be a two-stroke engine, three-stroke engine, four-stroke engine, five-stroke engine, or six-stroke engine. The engine 16 may also include any number of combustion chambers, pistons, and associated cylinders (e.g., 1-24). For example, in certain embodiments, the system 10 may include a large-scale industrial reciprocating engine having 4, 6, 8, 10, 16, 24 or more pistons reciprocating in cylinders. In some such cases, the cylinders and/or the pistons may have a diameter of between approximately 13.5-34 centimeters (cm). In some embodiments, the cylinders and/or the pistons may have a diameter of between approximately 10-40 cm, 15-25 cm, or about 15 cm. The system 10 may generate power ranging from 10 kW to 10 MW. In some embodiments, the engine 16 may operate at less than approximately 1800 revolutions per minute (RPM). In some embodiments, the engine 16 may operate at less than approximately 2000 RPM, 1900 RPM, 1700 RPM, 1600 RPM, 1500 RPM, 1400 RPM, 1300 RPM, 1200 RPM, 1000 RPM, 900 RPM, or 750 RPM. In some embodiments, the engine 16 may operate between approximately 750-2000 RPM, 900-1800 RPM, or 1000-1600 RPM. In some embodiments, the engine 16 may operate at approximately 1800 RPM, 1500 RPM, 1200 RPM, 1000 RPM, or 900 RPM. Exemplary engines 16 may include General Electric Company's Jenbacher Engines (e.g., Jenbacher Type 2, Type 3, Type 4, Type 6 or J920 FleXtra) or Waukesha Engines (e.g., Waukesha VGF, VHP, APG, 275GL), for example.

The internal combustion system 12 includes the engine 20 having an intake manifold 22, an exhaust manifold 32, and a controller 24 (e.g., an engine control unit (ECU), which may include a processor 26 and a memory component 28. The internal combustion system 12 also includes a throttle 30 that regulates the amount of air, or air-fuel mixture, entering the engine 20 via the intake manifold 22. The intake manifold 22 and the exhaust manifold 32 of the engine 20 are functionally coupled to the turbocharger 14. The turbocharger 14 includes a compressor 34 coupled to a turbine 36 via a drive shaft 38. The compressor 34 receives air via an air intake duct 40. The air (e.g., at atmospheric/barometric pressure) is drawn in via the air intake duct 40 under partial vacuum created by a compressor wheel in the compressor 34. The compressor wheel is driven by the shaft 38 which is driven by a turbine wheel in the turbine 36. The turbine wheel is driven by engine exhaust provided to the turbine 36 via an engine exhaust duct 42 which is connected to the exhaust manifold 32 of the engine 20.

The output of the compressor 34 is coupled to an intercooler 44 via a compressor discharge duct 46. The compressor wheel compresses intake air and forces it through the compressor discharge duct 46 to the intercooler 44 which functions as a heat exchanger removing excess heat from the turbocharged intake air. Turbocharged intake air is then channeled to the intake manifold 22, the throttle 30, and the engine 20. The throttle 30 creates a pressure differential depending on its pressure position, such that air pressure into the throttle 30 is at compressor discharge pressure (e.g., boost pressure) and air pressure out of the throttle 30 is at intake manifold pressure.

Some systems 10 include a wastegate 16 (e.g., wastegate valve) disposed in a wastegate enclosure 47, and coupled to a discharge duct 48. The discharge duct 48 couples the engine exhaust duct 42 to an exhaust discharge duct 50. The discharge duct 50 is also coupled to the turbine 36. Exhaust gas travels through the discharge duct 50 on its way to the exhaust stack 51, where the exhaust is expelled. The wastegate 16 functionally regulates the amount of engine exhaust provided to the turbine 36 of the turbocharger 14 and thus the compressor discharge pressure produced by the compressor 34. For example, by diverting engine exhaust in the engine exhaust duct 42 to the exhaust discharge duct 50, the wastegate 16 decreases exhaust mass airflow to the turbine 36 which decreases the compressor discharge pressure produced by the compressor 34. For example, the wastegate 16 may be closed during engine startup to direct the full engine exhaust through the turbine 30 to drive the turbine wheel which drives the shaft 38 and the compressor wheel until the intake manifold pressure reaches a minimum level. The more the wastegate 16 is open during operation of the engine 20, the more engine exhaust is diverted from the turbocharger 14 to regulate the intake manifold 22 pressure. The wastegate 16 may include any variable controlled valve (e.g. butterfly valve, gate valve, poppet valve, etc.).

The system 10 may also include a bypass valve 52 in a bypass duct 54. The bypass duct 54 couples the compressor discharge duct 46 to the engine exhaust duct 42. The bypass valve 52 functionally relieves pressure in the compressor discharge duct 46 and increases airflow through the compressor 34 by regulating airflow through the bypass duct 54. For example, the bypass valve 52 is closed during startup because the engine exhaust pressure in the engine exhaust duct 42 is greater than the compressor discharge pressure in the compressor discharge duct 46. Once the engine 20 is running at minimum idle speed, the bypass valve 52 is regulated (e.g., opened, closed, opened at various angles, etc.) to regulate compressor discharge pressure and mass airflow. In certain embodiments, the system 10 may not include a bypass valve 42.

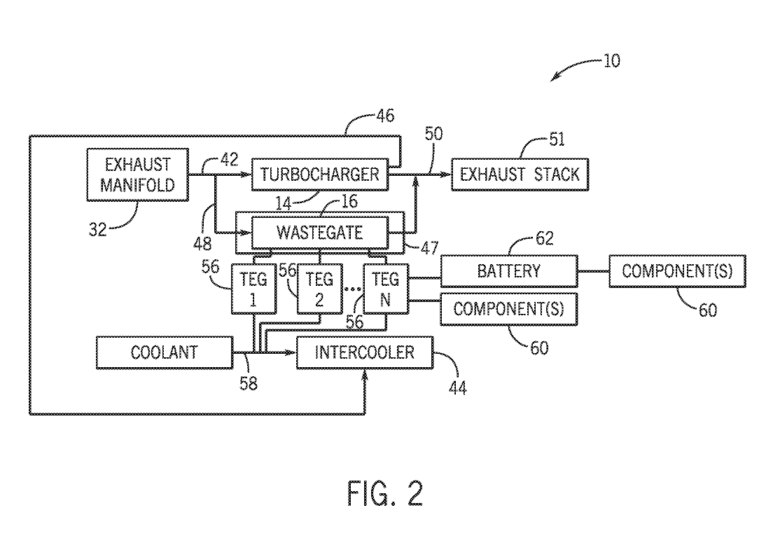

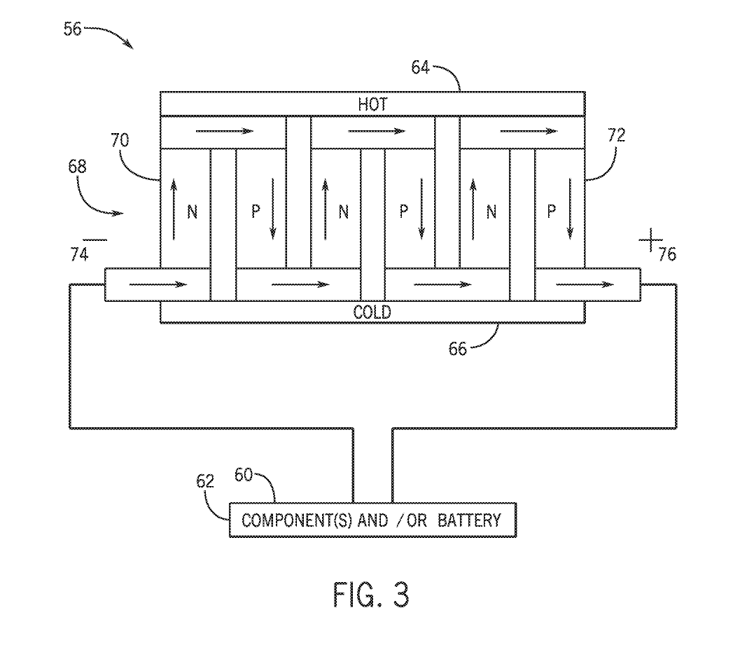

The system 10 shown in FIG. 1 also includes one or more thermoelectric generators (TEGs) 56 coupled between the wastegate enclosure 47 and the coolant inlet 58 to the intercooler 44. The TEG 56, which will be discussed in more detail with regard to FIGS. 2 and 3 may be used to convert temperature differences into electrical energy via the Seebeck effect. The TEG 56 may use the harvested electrical energy to improve the efficiency of the system 10. For example, the TEG 56 may be used to power one or more components that would otherwise be belt-driven (e.g., starter motor, electric oil pump, auxiliary power unit, electric water pump, compressed air module, down converter, modular HVAC, shore power and inverter, and the like). Powering one or more of these components using energy that would otherwise be wasted, rather than powering them with the engine, may improve the efficiency of the engine system 10.

The controller 24 may control the throttle 30, the wastegate valve 16, the bypass valve 52, and their associated actuators. The controller 24 sends control signals to the actuators of the throttle 30, the wastegate valve 16, and the bypass valve 52, to adjust the respective positions (e.g., open, close, open at a certain angle, etc.) of the throttle 30, the wastegate valve 16, and the bypass valve 52. The controller 24 may be coupled to various sensors and devices throughout the system 10 (including the internal combustion system 12 and the turbocharger 14).

It should be understood that in some embodiments, the system 10 may not include all of the components illustrated in FIG. 1. In addition, the system 10 may include additional components such as control components, aftertreatment components, and/or heat recovery components not pictured in FIG. 1. For example, the system 10 may include more than one intercooler 44, more than one TEG 56, etc. Also, the system 10 may include a variety of valves (e.g., fuel valves, pressure valves, etc.).

FIG. 2 is a schematic of the engine driven system 10 showing the one or more TEGs 56 in more detail. As was previously discussed with regard to FIG. 1, the wastegate 16 may be disposed in a wastegate enclosure 47 and coupled to a discharge duct 48 that couples the engine exhaust duct 42 and the exhaust discharge duct 50. The wastegate 16 regulates the amount of engine exhaust provided to the turbine 36 of the turbocharger 14 and in turn the compressor discharge pressure produced by the compressor 34. The one or more TEGs 56 may be coupled between the wastegate 16 or the wastegate enclosure 47 (which may or may not be part of the discharge duct 48) and the coolant inlet 58 to the intercooler 44. The one or more TEGs 56 may be used to harvest energy to power one or more components 60 directly, charge a battery 62, or both. The hot side of each TEG 56 may be coupled to the wastegate 16 or the wastegate enclosure 47, which is heated by hot exhaust air flowing through the discharge duct 48. The cold side of each TEG 56 is coupled to the coolant inlet 58 to the intercooler 44. However, it should be understood that the TEG 56 may be coupled to some other coolant source. For example, the coolant may be water, air, or any other fluid having a lower temperature than the wastegate enclosure 47. Using the Seebeck effect, each TEG 56 converts the difference in temperatures between the hot side and the cold side into electricity. The harvested electrical energy may then be used to charge batteries 62 or to power various components 60 (e.g., starter motor, electric oil pump, auxiliary power unit, electric water pump, compressed air module, down converter, modular HVAC, shore power and inverter, prelube pump, preheater water pump, and the like) that would otherwise be driven by the engine 20 (e.g., using a belt). By powering these components 60 with a TEG 56 using energy that would otherwise be wasted, rather than powering the components 60 with the engine 20 directly, the efficiency of the system 10 may be improved.

FIG. 3 is a schematic of one embodiment of a TEG 56, as would be used in the engine driven system 10. As shown in FIG. 3, the TEG may include a hot side heat exchanger 64 and a cold side heat exchanger 66. Thermoelectric materials 68 (e.g., n-doped semiconductors 70 and p-doped semiconductors 72) may be sandwiched between the hot side 64 and the cold side 66. In some embodiments, the TEG 56 may also include a compression assembly system, which holds the TEG 56 together. The temperature difference between the hot side 64 and the cold side 66 creates an electric potential (i.e., a voltage) in the thermoelectric materials 68. In the embodiment shown in FIG. 3, the thermoelectric materials 68 comprise alternating n-doped semiconductors 70 and p-doped semiconductors 72 connected in series such that the voltages across the thermoelectric materials 68 are added to create a larger voltage between the negative end 74 (e.g., negative terminal) and the positive end 76 (e.g., positive terminal) of the TEG 56. One or more components 60 or batteries 62 may then be connected across the terminals 74, 76 to power the one or more components 60 and/or charge the battery 62. In one embodiment, the thermoelectric material 68 may include lead tulluride (PbTe), which may be doped, as the p-type semiconductor 72 and bismuth telluride (Bi₂Te₃) as the n-type semiconductor 70. However, other embodiments may use other thermoelectric materials, such as Bi₂Se₃, Sb₂Te₃, or other bismuth chalcogenides, inorganic clathrates (Ba₈Ga₁₆Ge₃₀, Ba₈Ga₁₆Si₃₀), magnesium group IV compounds (Mg₂Si, Mg₂Ge, Mg₂Sn), silicides, skutterudite thermoelectrics, oxide thermoelectrics, half Heusler alloys, silicon germanium, sodium cobaltate, tin selenide, and the like.

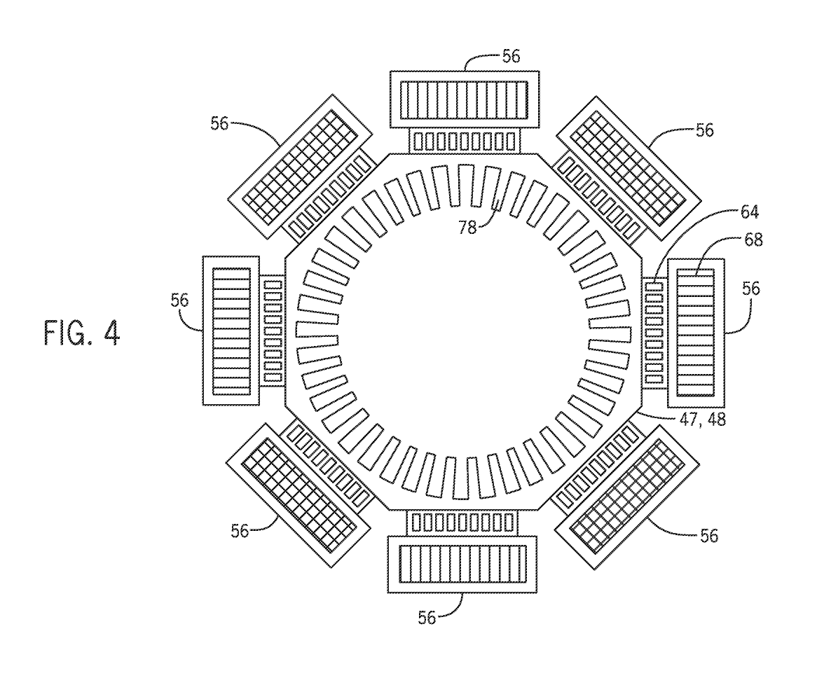

FIG. 4 shows one embodiment of the system 10 in which multiple TEGs 56 (in FIG. 4 there are 8) are disposed about the wastegate enclosure 47 or the discharge duct 48. Note that the interior of the discharge duct 48 may be shaped like a heat sink in order to increase surface area and draw more heat from the exhaust flowing through the discharge duct 48. In the embodiment shown in FIG. 4, the temperature of the exhaust flowing through the discharge duct 48 may be approximately 600° C., while the temperature of the coolant may be approximately 50° C.

The thermoelectric efficiency of the TEGs may be expressed by the following equation:

$$η = ( \frac{{T}_{H} - {T}_{C}}{{T}_{H}} ) ( \frac{\sqrt{1 + ZT} - 1}{\sqrt{1 + ZT} + \frac{{T}_{C}}{{T}_{H}}} ) \qquad ( 1 )$$

wherein η is the thermoelectric efficiency, T_{II} is the absolute temperature of the hot reservoir (e.g., wastegate enclosure 47 or discharge duct 48) in Kelvin, T_{C} is the absolute temperature of the cold reservoir (e.g., coolant inlet 58) in Kelvin, and ZT is the figure of merit, which is specific to a given thermoelectric material.

For example, in an embodiment using lead telluride as a thermoelectric material, if the temperature of the wastegate enclosure 47 is approximately 904 K, and the temperature of the coolant inlet is 291 K, and lead telluride has a ZT of 0.8 at the mean temperature (i.e., the mean temperature of the source and sink), then the efficiency of the thermoelectric generator is approximately 13.9%. Assuming the that lead telluride has a thermal conductivity of 1.56 W/mK, the wastegate enclosure 47 has an inner radius of 40 mm, an outer radius of 44.3 mm, and a length of 400 mm, a temperature difference between hot and cold sides of approximately 612 K produces a heat flow rate through the lead telluride of approximately 23.525 kW. If the TEG 56 has a thermal efficiency of approximately 13.9%, then the TEG 56 will produce approximately 3.275 kW. Accordingly, if used in conjunction with a VHP 7044gsi engine from General Electric Company of Schenectady, New York running at 1000 rpm, which produces 1047 kW, the use of TEGs 56 will increase efficiency of the system 10 by about 0.313%. It should be understood, however, that this merely an example and that other values may be possible.

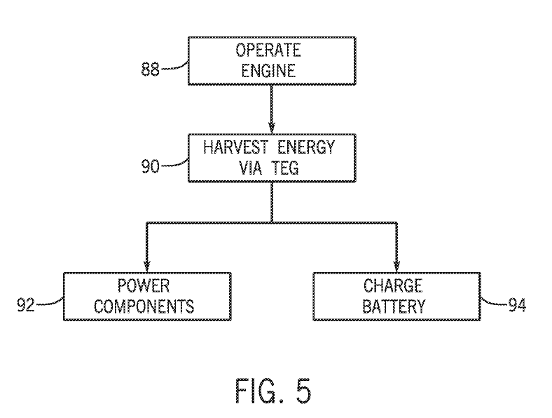

FIG. 5 shows a process for using a TEG 56 to power components 60 or charge a battery 62 in a system 10. In block 88, an internal combustion engine driven system 10 is operated. As discussed with regard to FIGS. 1 and 2, the system 10 may include an engine 20, a turbocharger 14, a wastegate 16 to control the amount of engine exhaust directed to the turbocharger 14, and an intercooler.

In block 90 energy is harvested from the wastegate 16 or the wastegate enclosure 47 (e.g. discharge duct 48) using one or more TEGs 56. Each of the one or more TEGs 56 may include a hot side (e.g., hot side heat exchanger 64), a cold side (e.g., cold side heat exchanger 66), and one or more thermoelectric materials 68 sandwiched between the hot side 64 and the cold side 66. In some embodiments, the thermodynamic material 68 may be lead telluride. In other embodiments, the one or more thermoelectric materials 68 may include a p-type semiconductor 72 (e.g., lead telluride) and an n-type semiconductor 70 (e.g., bismuth telluride). In some embodiments, each of the one or more TEGs 56 may include a compression assembly system to hold the TEG 56 together. In some embodiments, the one or more TEGs 56 may include one or more positive leads and one or more negative leads for connecting components 60 or batteries 62. The hot side 64 of each of the one or more TEGs 56 is connected to the wastegate 16. It should be understood that in some embodiments, the one or more TEGs may be connected to the enclosure 47 around the wastegate 16 (e.g., discharge duct 48). In some embodiments, the one or more TEGs 56 may be coupled directly to the wastegate 16. In some embodiments, the one or more TEGs 56 may be disposed about the wastegate enclosure 47 (discharge duct 48). In other embodiments, the TEGs 56 may be directly or indirectly coupled to the wastegate 16 or wastegate enclosure 47. The cold side 66 of each of the TEGs 56 may be connected to the coolant inlet 58 to the intercooler 44, or some other coolant source. The cold side 66 may be directly or indirectly coupled to the coolant inlet 58 to the intercooler 44 or other coolant source.

In block 92, the one or more TEGs 56 may be used to power one or more components 60. The components 60 and/or batteries 62 may be connected to the one or more positive terminals and negative terminals of the one or more TEGs 56. The one or more TEGs 56 may then be used to power components 60 that were previously powered directly by the engine 20 (e.g., using a belt). Such an arrangement reduces the load on the engine 20, increases efficiency, and uses energy that would otherwise be wasted to power one or more components 60 or charge a battery 62. In block 94, the one or more TEGs 56 may be used to charge one or more batteries 62. The batteries may be used to power various components 60 or provide a source of power for other reasons.

Technical effects of the disclosed embodiments include improving the efficiency of an internal combustion engine driven system 10 by harvesting previously wasted energy from the system and using that energy to drive components 60 that were previously driven directly by the engine. In some embodiments, implementation of the disclosed system and techniques may improve overall efficiency of the system by 0.3%, resulting in approximately 3 kW more power (assuming a VHP 7044gsi engine running at 1000 rpm). Similarly, the systems and techniques disclosed herein may improve fuel consumption by 0.65%. Additionally, because a thermoelectric generator, unlike a belt-drive system, has no moving parts, maintenance of the system becomes simpler.

This written description uses examples to disclose the subject matter, including the best mode, and also to enable any person skilled in the art to practice the claimed subject matter, including making and using any devices or systems and performing any incorporated methods. The patentable scope of the subject matter is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

1. A system comprising:
a turbocharger comprising a turbine and a compressor, wherein the turbocharger is configured to be coupled to an internal combustion engine;
a wastegate coupled to the turbine, wherein the wastegate is disposed within a wastegate enclosure; and
one or more thermoelectric generators configured to generate energy from engine exhaust flowing through the wastegate, each of the one or more thermoelectric generators comprising:
a hot side coupled to the wastegate enclosure;
a cold side coupled to a coolant supply; and
one or more thermoelectric materials disposed between the hot side and the cold side.

2. The system of claim 1, wherein the coolant supply comprises a coolant inlet to an intercooler.

3. The system of claim 1, wherein the one or more thermoelectric generators are used to power one or more components of the system.

4. The system of claim 3, wherein the one or more components are a starter motor, an electric oil pump, an auxiliary power unit, an electric water pump, a compressed air module, a down converter, a modular HVAC, a prelube pump, a preheater water pump, or a combination thereof.

5. The system of claim 3, wherein the one or more thermoelectric generators are used to charge a battery.

6. The system of claim 1, wherein the one or more thermoelectric materials comprise an n-doped semiconductor and a p-doped semiconductor.

7. The system of claim 1, wherein the one or more thermoelectric materials comprise PbTe or CsBi₄Te₆.

8. The system of claim 1, wherein the one or more thermoelectric materials comprise Bi₂Te₃ or Zn₄Sb₃.

9. An engine driven system comprising:
an internal combustion engine;
an intake manifold disposed upstream of the internal combustion engine;
an exhaust manifold disposed downstream of the internal combustion engine;
a turbocharger coupled to the internal combustion engine, wherein the turbocharger comprises a turbine and a compressor;
a wastegate coupled to the turbine and disposed within a wastegate enclosure, wherein the wastegate in operation regulates an amount of engine exhaust to the turbine by diverting engine exhaust away from the turbine;
an intercooler coupled to the turbocharger and the intake manifold;
a coolant supply configured to supply coolant to a coolant inlet of the intercooler; and
a thermoelectric generator configured to generate energy from engine exhaust flowing through the wastegate, the thermoelectric generator comprising:
a hot side coupled to the wastegate enclosure;
a cold side coupled to the coolant inlet of the intercooler;
one or more thermoelectric materials disposed between the hot side and the cold side.

10. The engine driven system of claim 9, wherein the thermoelectric generator is used to power a starter motor, an electric oil pump, an auxiliary power unit, an electric water pump, a compressed air module, a down converter, a modular HVAC, a prelube pump, a preheater water pump, or a combination thereof.

11. The engine driven system of claim 9, wherein the thermoelectric generator is used to charge a battery.

12. The engine driven system of claim 9, wherein the one or more thermoelectric materials comprise an n-doped semiconductor and a p-doped semiconductor.

13. The engine driven system of claim 9, wherein the one or more thermoelectric materials comprise PbTe or CsBi₄Te₆.

14. The engine driven system of claim 9, wherein the one or more thermoelectric materials comprise Bi₂Te₃ or Zn₄Sb₃.

15. The engine driven system of claim 9, wherein the wastegate enclosure comprises a discharge duct, and wherein the one or more thermoelectric generators are disposed about the discharge duct.

16. A method comprising:
operating an engine driven system, wherein the engine driven system comprises:
an internal combustion engine;
a turbocharger coupled to the internal combustion engine;
a wastegate coupled to the turbocharger and disposed within a wastegate enclosure; and
an intercooler having a coolant inlet;
harvesting energy via one or more thermoelectric generators, wherein each of the one or more thermoelectric generators comprises:
a hot side coupled to the wastegate enclosure;
a cold side coupled to the coolant inlet of the intercooler; and
one or more thermoelectric materials disposed between the hot side and the cold side; and
powering one or more components using energy harvested by the one or more thermoelectric generators.

17. The method of claim 16, wherein the one or more components comprise a starter motor, an electric oil pump, an auxiliary power unit, an electric water pump, a compressed air module, a down converter, a modular HVAC, a prelube pump, a preheater water pump, or a combination thereof.

18. The method of claim 16, comprising charging one or more batteries using energy harvested by the one or more thermoelectric generators.

19. The method of claim 16, wherein the one or more thermoelectric materials comprise PbTe, CsBi₄Te₆, Bi₂Te₃, or Zn₄Sb₃.

20. The method of claim 16, wherein the one or more thermoelectric generators are disposed about the wastegate enclosure.
